(19) United States
(12) Patent Application Publication
(10) Pub. No.: US 2007/0229119 A1
(43) Pub. Date: Oct. 4, 2007

(54) Comparator circuit

(75) Inventors: Masato Onaya, Ora-gun (JP); Shunsuke Serizawa, Maebashi-shi (JP)

Correspondence Address: OSHA LIANG L.L.P., 1221 MCKINNEY STREET, SUITE 2800, HOUSTON, TX, 77010, US

(73) Assignee: Sanyo Electric Co., Ltd., Osaka (JP)

(21) Appl. No.: 11/728,626

(22) Filed: Mar. 27, 2007

(30) Foreign Application Priority Data
Mar. 29, 2006 (JP) 2006-91504

(51) Int. Cl. H03K 5/22

(52) U.S. Cl. 327/63

(57) ABSTRACT

It is intended to provide a comparator circuit which uses a switched capacitor and has a small circuit size. An input INA is supplied to positive input terminals of comparators Com1 and Com2 through a capacitor Ca by means of a switch SW1. An input INB is supplied to a negative input terminal of the comparator Com1 through a capacitor Cb1 by means of a switch SW2, and in addition, is supplied to a negative input terminal of the comparator Com2 after being inverted through the use of a capacitor Cb2 by means of switches SW3 and SW4. Outputs from the comparators Com1 and Com2 are input to an exclusive OR circuit EXOR, which outputs a result of judgment as to whether or not the input INA is within the range extending between the positive input INB and the negative input INB.

### PRIORITY INFORMATION

This application claims priority to Japanese Patent Application No. 2006-091504 filed on Mar. 29, 2006, which is incorporated herein by reference in its entirety.

### BACKGROUND

1. Technical Field

The present invention relates to a comparator circuit which compares a first input and a second input.

2. Related Art

Conventionally, a device for processing video signals, such as a TV receiver or a VCR, has a circuit for calculating a correlation of video signals for each horizontal scanning line. For example, in a Y/C separation circuit for separating a luminance signal and a color signal from a composite signal in which the luminance signal and the color signal are superposed, Y/C separation is performed by addition or subtraction of video signals of two horizontal scanning lines. Therefore, when selecting, from among two horizontal lines, one horizontal line with respect to which addition or subtraction for one horizontal line is to be performed, it is preferable to use a more highly correlated line. More specifically, it is possible to select a more highly correlated adjacent horizontal line in relation to luminance signals to obtain a luminance signal by adding the video signals of the horizontal lines, and to obtain a color signal by subtraction.

To this end, a circuit for detecting such correlation is necessary, and various types of circuits have been proposed. For example, reference can be made to JP 2003-32701 A.

### SUMMARY

According to the present invention, it is possible to produce non-inverted and inverted signals for two input signals using a switched capacitor circuit, and to directly compare these signals in a comparator to thereby obtain a result of comparison. As a result, it is not necessary to perform full-wave rectification or the like before the comparison.

### BRIEF DESCRIPTION OF THE DRAWINGS

An embodiment of the present invention will be described in detail with reference to the following drawings, wherein:

FIG. 1 shows a comparator circuit according to an embodiment of the present invention;

FIG. 2 shows an example of comparison; and

FIG. 3 shows another example structure.

### DETAILED DESCRIPTION

An embodiment of the present invention will be described below with reference to the drawings.

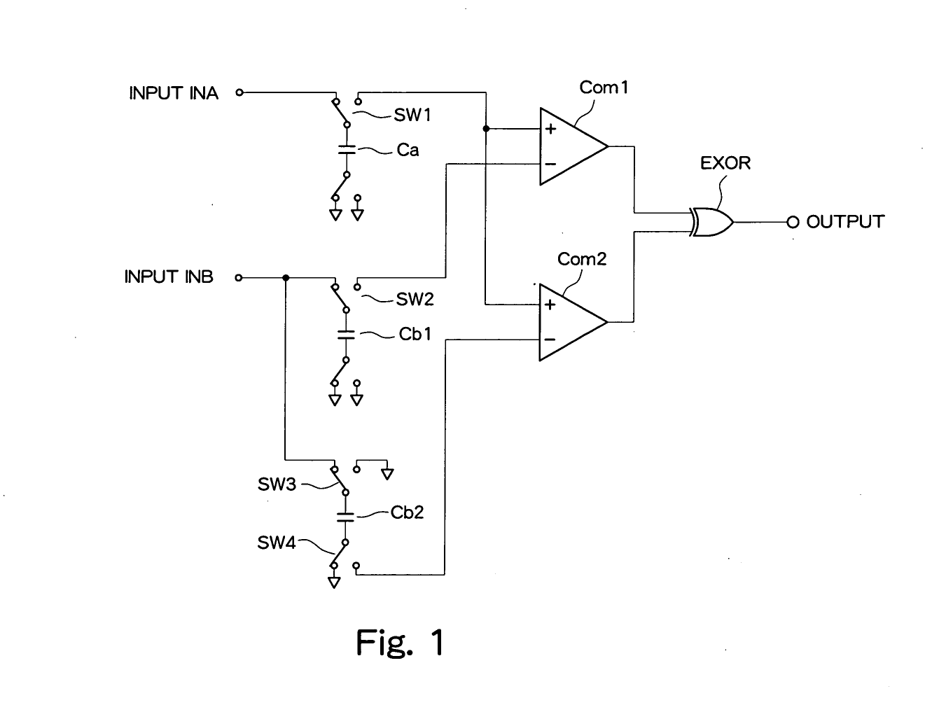

FIG. 1 shows a structure of the embodiment. A first input INA and a second input INB are input as two input signals to be compared. The input INA is input to a switch SW1, and the switch SW1 is connected to an input side of a capacitor Ca. The switch SW1 has an input terminal to which the input INA is supplied, and an output terminal, and these are switchable to the input side of the capacitor Ca. A reference side, which is another terminal of the capacitor Ca, is connected to a reference of a preset reference voltage.

Also, another input, or the input INB, is input to a switch SW2, and the switch SW2 is connected to an input side of a capacitor Cb1. The switch SW2 has an input terminal to which the input INB is supplied, and an output terminal, and these are switchable to the input side of the capacitor Cb1. A reference side, which is another terminal of the capacitor Cb1, is connected to a reference of a preset reference voltage.

Also, the input INB is input to a switch SW3, and the switch SW3 is connected to an input side of a capacitor Cb2. The switch SW3 has an input terminal to which the input INB is supplied, and a reference terminal which is connected to a reference of a preset reference voltage, and these are switchable to the input side of the capacitor Cb2. A reference side, which is another terminal of the capacitor Cb2, is connected to a switch SW4, and the switch SW4 has a reference terminal which connects the reference side of the capacitor Cb2 to a reference of a preset reference voltage, and an output terminal, and is switchable to the reference side of the capacitor Cb2.

An output side of the switch SW1 is connected to a positive input terminal of a comparator Com1, and an output side of the switch SW2 is connected to a negative input terminal of the comparator Com1. Further, the output side of the switch SW1 is also connected to a positive input terminal of a comparator Com2, and an output terminal of the switch SW4 is connected to a negative input terminal of the comparator Com2.

Thus, the comparator Com1 compares the input INA and the input INB, and outputs an “H” level when the input INA is greater than the input INB. Also, the comparator Com2 compares the input INA and a signal obtained by inverting the input INB relative to a reference (referred to as “inverted INB”), and outputs an “H” level when the input INA is lower than the inverted INB.

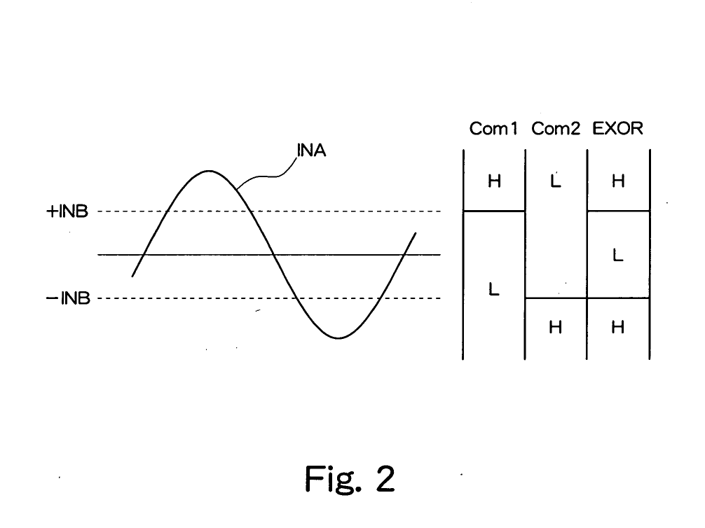

For example, it is assumed that the input INA is an alternating current signal and the input INB is a direct current voltage having a constant voltage, and then, as shown in FIG. 2, when the reference is set to 0, both the comparators Com1 and Com2 output an “L” level when the input INA is between the positive input INB and the negative input INB (± input INB), the comparator Com1 outputs an “H” level when the input INA is higher than the input INB, and the comparator Com2 outputs an “H” level when the input INA is lower than the inverted INB.

Outputs from the comparators Com1 and Com2 are input to an exclusive OR circuit EXOR. Thus, as shown in FIG. 2, the exclusive OR circuit EXOR outputs an “L” level when the input INA is between the positive input INB and the negative input INB, and the exclusive OR circuit EXOR outputs an “H” level when the input INA is outside the range extending between the positive input INB and the negative input INB.

In this way, by means of the circuit shown in FIG. 1, it is possible to compare two input signals, the input INA and the input INB, to obtain a signal indicating the degree of similarity therebetween.. More specifically, the shorter the period of time during which the exclusive OR circuit EXOR outputs an “H” level, the more similar the two signals are.

As described above, according to the present embodiment, it is possible to produce non-inverted and inverted signals from two input signals of the inputs INA and INB using a switched capacitor circuit, and to directly compare these signals in a comparator to thereby obtain a result of comparison. As a result, the circuit size can be reduced because it is not necessary to perform full-wave rectification or the like before the comparison, and an operational amplifier is no longer necessary.

In a YC separation circuit for video signals, it is necessary to judge, with respect to a signal on a horizontal scanning line to be processed, which of signals on two adjacent horizontal scanning lines is more similar to the signal to be processed. It is suitable for the circuit of the present embodiment to be used in this judgment.

For example, a difference signal of video signals on two lines can be compared with a threshold level. As the threshold level, a value indicating the degree below which it can be judged that there is a sufficient correlation is used. A difference signal between a target line and its upper adjacent line and a difference signal between the target line and its lower adjacent line are compared, and the line for which the “H” level period is shorter is judged to have a higher correlation. When there is no “H” level period, either of the lines may be selected.

Further, a video signal processing circuit in which a switched capacitor is employed has been proposed in commonly assigned Japanese Patent Application No. 2005-219375.

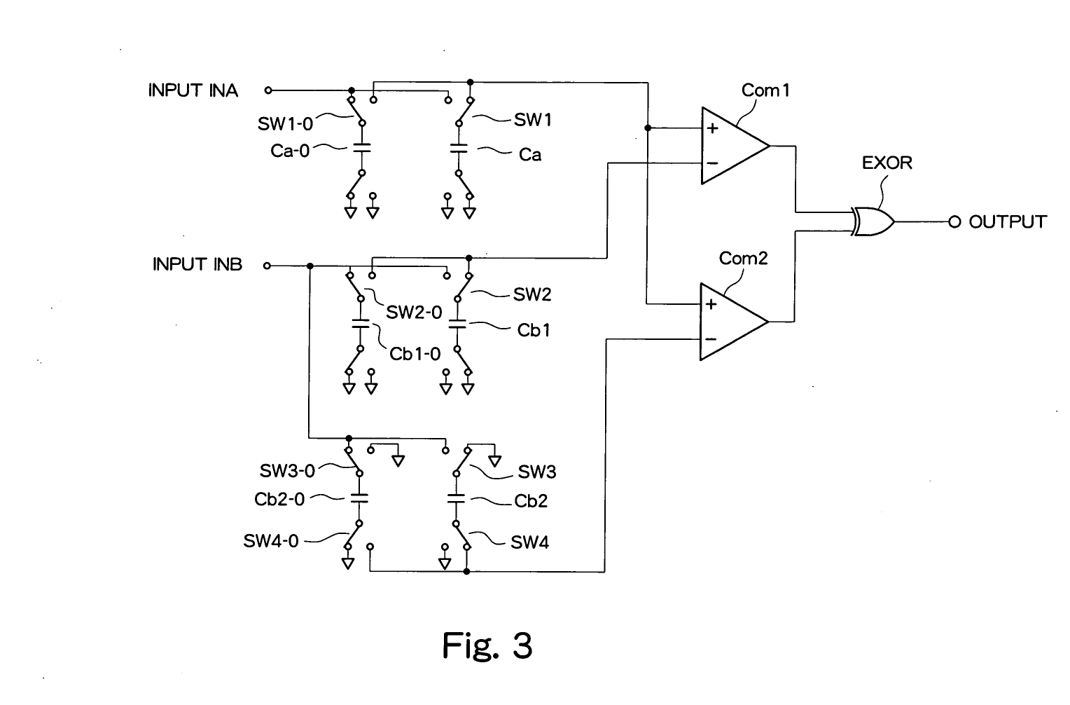

FIG. 3 shows another example structure. In this example, capacitors Ca, Cb1, and Cb2 are provided in pairs, and are configured such that, while one of a pair provides an output, the other is charged by an input signal.

More specifically, in addition to the capacitor Ca, a capacitor Ca-0 is provided, to an input side of which a switch SW1-0 is connected, with an input terminal of the switch SW1-0 being connected to the input INA, and an output terminal of the switch SW1-0 being connected to the positive input terminal of the comparator Com1. When the switch SW1 connects the input side of the capacitor Ca to the input terminal, the switch SW1-0 connects the input side of the capacitor Ca-0 to the output terminal, and when the switch SW1 connects the input side of the capacitor Ca to the output terminal, the switch SW1-0 connects the input side of the capacitor Ca-0 to the input terminal. In this way, the capacitor Ca and the capacitor Ca-0 can be alternately used to supply the input INA to the positive input terminal of the comparator Com1.

Similarly, a capacitor Cb1-0 and a switch SW2-0 are provided in connection with the capacitor Cb1, and a capacitor Cb2-0, a switch SW3-0, and a switch SW4-0 are provided in connection with the capacitor Cb2, so that these pairs of capacitors can be used alternately.

What is claimed is:

1. A comparator circuit for comparing a first input and a second input, the comparator circuit comprising:
a first capacitor for storing and outputting a first input, wherein an input side is alternately connected to a first input and to an output, and a reference side is connected to a reference terminal having a reference voltage;
a second capacitor for storing and outputting a second output, wherein an input side is alternately connected to a second input and to an output, and a reference side is connected to a reference terminal;
a third capacitor for storing, then inverting and outputting, a second input, wherein an input side is alternately connected to a second input and to a reference terminal, and a reference side is alternately connected to a reference terminal and to an output;
a first comparator for comparing an output from the first capacitor and an output from the second capacitor; and
a second comparator for comparing an output from the first capacitor and an output from the third capacitor, wherein
a first input and a second input are compared based on results of comparisons performed in the first comparator and the second comparator.

2. The comparator circuit according to claim 1, wherein:
an output from the first capacitor is input to a positive input of the first comparator and an output from the second capacitor is input to a negative input of the first comparator so that the first comparator compares the output from the first capacitor and the output from the second capacitor;
an output from the first capacitor is input to a positive input of the second comparator and an output from the third capacitor is input to a negative input of the second comparator so that the second comparator compares the output from the first capacitor and the output from the third capacitor; and
outputs from the first and second comparators are input to an exclusive OR circuit, and an output from the exclusive OR circuit is output as a result of comparison.

3. The comparator circuit according to claim 2, wherein:
the first input is an alternating current signal that fluctuates about a reference level, and the second input is a signal indicating a threshold direct current level; and
the exclusive OR circuit outputs a signal identifying whether an amplitude of the alternating current signal is within or outside a range extending between positive and negative thresholds determined by the second input.
